(19) United States
(12) Patent Application Publication
(10) Pub. No.: US 2015/0279824 A1
(43) Pub. Date: Oct. 1, 2015

(54) ELECTRONIC PACKAGE AND METHOD OF FORMING AN ELECTRONIC PACKAGE

(71) Applicants: Vijay K. Nair, Mesa, AZ (US); Chuan Hu, Chandler, AZ (US)

(72) Inventors: Vijay K. Nair, Mesa, AZ (US); Chuan Hu, Chandler, AZ (US)

(21) Appl. No.: 14/228,685

(22) Filed: Mar. 28, 2014

(51) Int. Cl. H01L 25/16; H01L 23/31; H01L 21/768; H01L 23/29; H01L 23/528; H01L 23/532; H01L 25/00; H01L 21/56

(52) U.S. Cl. CPC H01L 25/16; H01L 25/50; H01L 23/3107; H01L 21/565; H01L 23/293; H01L 23/528; H01L 23/53228; H01L 21/768

(57) ABSTRACT

An electronic package that includes a mold that includes at least one passive component, each of the passive components including electric conductors that are exposed from the mold, and a first conductive layer directly attached to the mold such that the conductive layer touches the mold and the electrical conductors that are exposed from the mold. A method that includes removing a temporary carrier from a mold that includes electronic devices, wherein electric conductors on the electronic devices are exposed once the temporary carrier is removed from the mold, and covering the mold with a first conductive layer such that the first conductive layer covers the mold and is electrically connected to the exposed electric conductors on the electronic devices.

### TECHNICAL FIELD

Embodiments described herein generally relate to an electronic package and methods of forming an electronic package.

### BACKGROUND

Surface-mount (SMT) passive components are a high volume commodity in the electronic component industry today. FIG. 1 shows the typical surface morphology of a SMT passive electronic component 1.

Conventional SMT passive components are typically produced with a relatively less stringent dimensional accuracy. In addition, the conductors 2 on conventional SMT passive components typically have a rough surface finish with solder.

One of the manufacturing issues associated with using conventional SMT passive components are that the passive components don't have good dimensional accuracy and the component placement accuracy of existing SMT pick and place machines (such as chip shooters), which are used for the passive component placement with high throughput, is not sufficient to make reliable metal-to-metal connection when a traditional embedded wafer level ball grid array (eWLB) process is used to embed passive components in the molding compound.

FIG. 2 shows one of the problematic issues associated with using traditional fabrication technology for embedding passive electronic components. As discussed above, the surface finish of the conductors (e.g., metal pads) on a typical passive electronic component is much worse than that on a typical silicon device. This rough finish surface finish and poor dimensional accuracy may cause an unacceptable level of surface contamination risk on the conductors of a passive electronic component. In some cases, even clean metal pads might have a finish that is too rough or have a different metallization that is not robust enough to maintain integrity or have surface contamination through the buildup process.

As discussed above, the dimensional specifications of commercially available passive electronic components are not very tight. In addition, the components pick and placement accuracy is also not as high as that of silicon dies. These two factors may cause the passive electronic components to be shifted or tilted after placement.

FIG. 3 illustrates a prior art electronic package 3 that includes a silicon die 4 embedded in a mold 5. The silicon die 4 is connected to passive electronic components 1 at a board 6 level.

FIG. 4 illustrates a prior art electronic package 6 that is at least partially formed using current eWLB processing technology. The electronic package 6 includes passive electronic components 1 that are embedded in a mold 7. The passive electronic components 1 are interconnected to the silicon die (not shown in FIG. 4) using two buildup layers 8A, 8B and two metal layers 9A, 9B.

Current eWLB processing technology typically begins by assembling all passive electronic components on a temporary carrier tape (not shown). A molding compound (MC) is then placed over the passive electronic components to form the mold. Eventually, the silicon dies are assembled onto an opposing side of the built up substrate. The interconnection between the silicon die and the passive electronic components is accomplished through the buildup layers and the two metal layers.

### BRIEF DESCRIPTION OF THE DRAWINGS

FIG. 1 shows typical morphology of a prior art SMT passive electronic component.

FIG. 2 shows some of the problematic issues associated with using prior art fabrication technology for embedding passive electronic components.

FIG. 3 illustrates a silicon die that is embedded in a mold and connected to passive electronic components at a board level using prior art fabrication techniques.

FIG. 4 illustrates a prior art electronic package that is at least partially formed using current eWLB processing technology.

FIG. 5 shows some of the benefits of the methods described herein that are associated with pick and place processing of passive electronic components when using SMT tools.

FIG. 6 illustrates one of the example electronic packages described herein.

FIG. 7 illustrates a flow diagram of an example method of forming an electronic package.

FIGS. 8A-F show corresponding assemblies for portions of the method shown in FIG. 7.

FIG. 9 shows a comparison between the conventional eWLB process steps and the method shown in FIG. 7.

FIG. 10 is a block diagram of an electronic device incorporating at least one electronic package and/or method described herein.

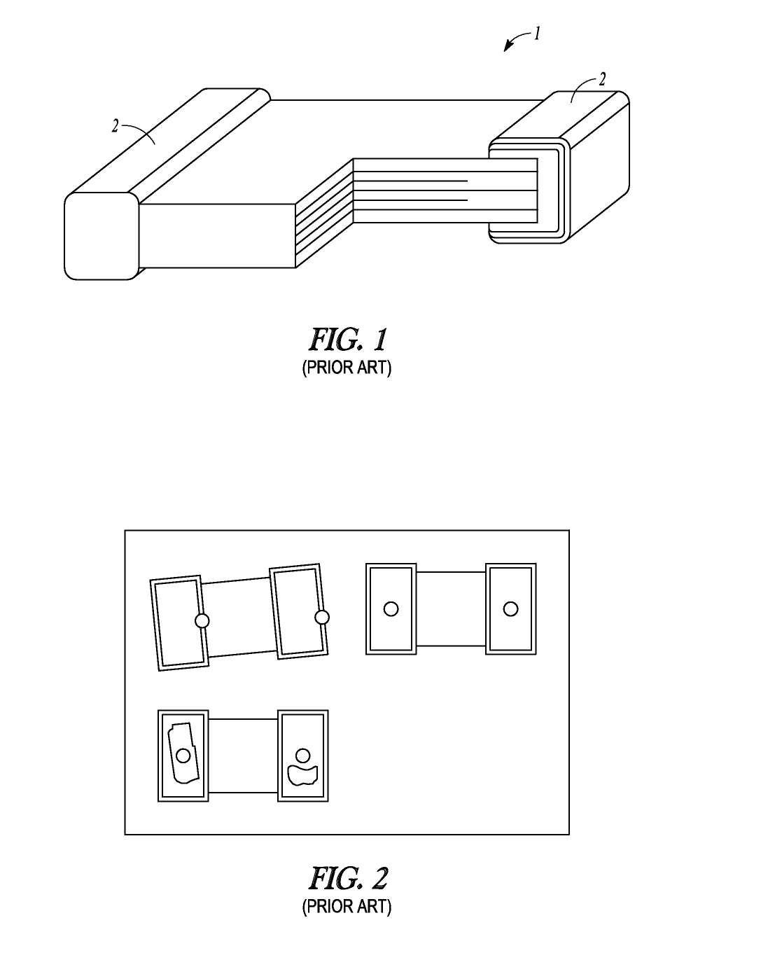

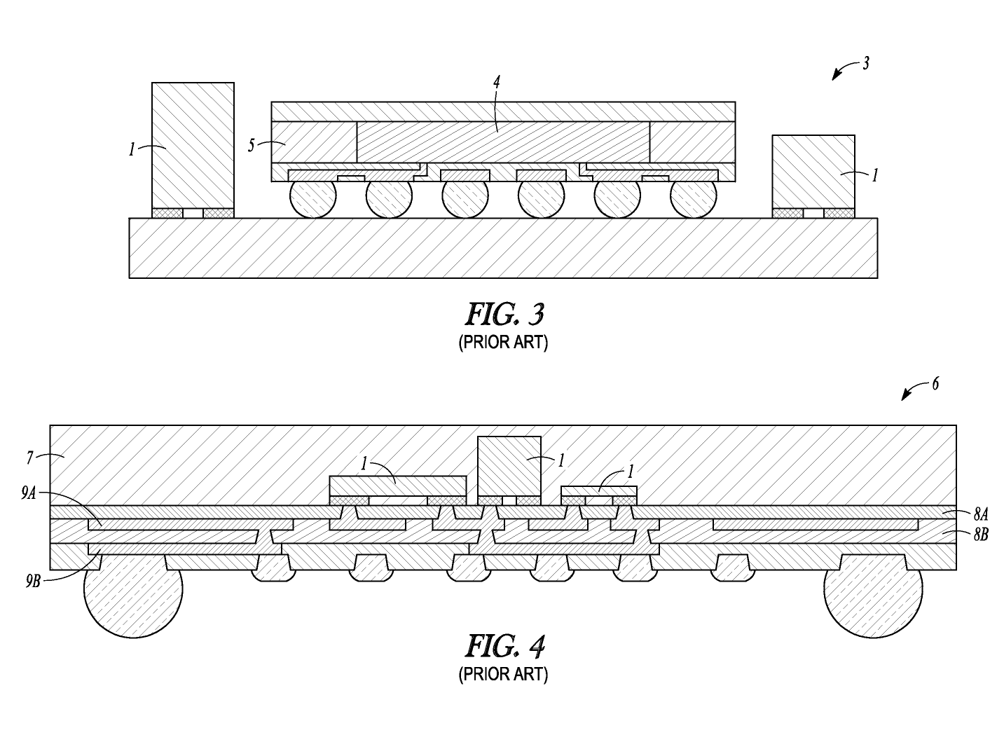

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the wafer or substrate.

The electronic packages and methods described herein at least partially relate to relatively low-cost silicon packages that integrate low-cost commercially available passive components with less stringent dimensional and metal termination specifications (of thickness, roughness, radius of curvature, material, flatness, etc.). Therefore, the electronic packages and methods described herein may produce a relatively higher yield.

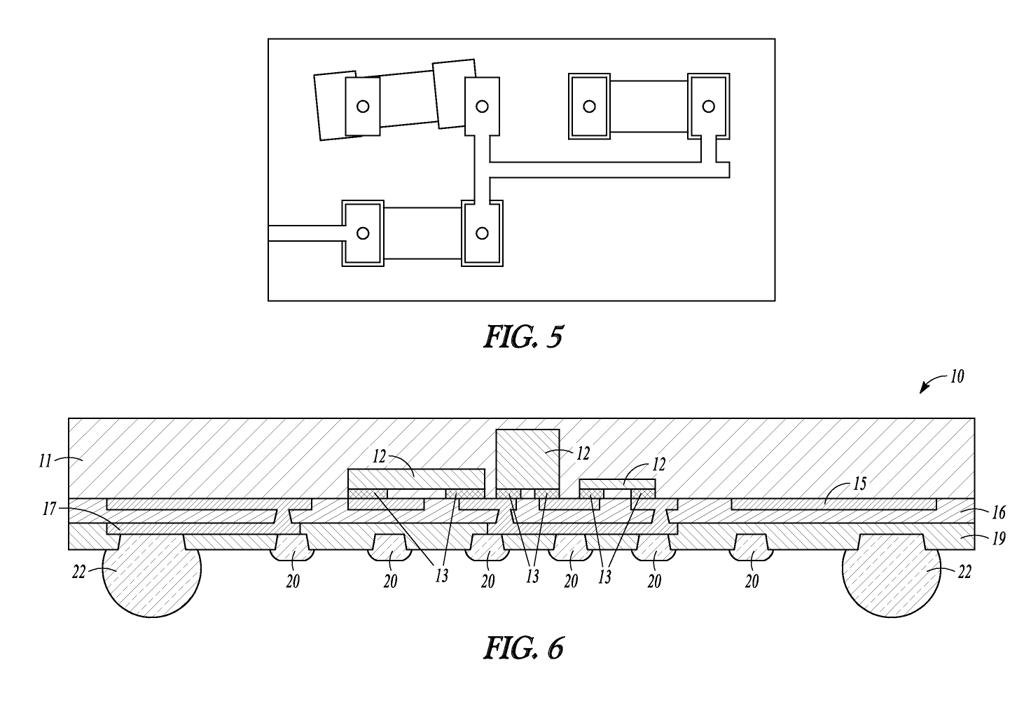

FIG. 5 shows some of the benefits that are associated with pick and place processing of passive electronic components when using SMT tools according to the methods described herein.

Current eWLB processing technology is primarily employed in order to fan out silicon ICs (e.g., dies). The electronic packages and methods described herein may correct all the process issues discussed above with some simple routing on the direct metal layer (e.g., larger lines and connection pads). In addition, the electronic packages and methods described herein may replace a more expensive semi additive metallization with a lower cost subtractive metallization step. The electronic packages and methods described herein may also provide a relative cost saving by utilizing standard passive metal termination without requiring extensive metal finishing (e.g., plating).

In addition, the electronic packages and methods described herein may not only eliminate two fabrication steps but at the same time improve fabrication yield by making robust metal connection directly with cheaper and more mature passive components (and not through a via opening as is done in conventional processes). Since the first metal layer is deposited or plated directly onto the exposed metal pads of the passive electronic components over the whole area of the molded wafer, a very robust metal connection to the passive electronic components may be created in the electronic packages and methods described herein. The interconnect yield may also be improved since there is no need to drill vias through the buildup layer.

The electronic packages and methods described herein may also have the potential to reduce size in x, y and z dimensions of the electronic package. This reduction in the size of the electronic package may (i) reduce form factor; and/or (ii) improve RF performance due to shorter interconnects between Radio receiver types chips and passive electronic components.

In some forms, the electronic packages and methods described herein may integrate ICs and other electronic components (active and passives) in a small form factor RF package using eWLB technology. In some forms, all RF passive components are first placed on a temporary carrier tape and molded using a molding compound (MC).

The ICs may then be soldered on the eWLB package after the full buildup and reflow. The interconnection between the IC and passives may be done using two metal layers. In addition, the electronic package may be connected to a ball grid array (BGA) using the top metal layer. The bottom metal layer may provide some local routing, grounding, and interconnection to the rough metal conductors of the passive electronic components.

Therefore, the electronic packages and methods described herein may allow for integration of a large number of passive electronic components in a very small form factor electronic package. As an example, a large number of passive electronic components may be needed for RF subsystems and associated ICs (like RF transceivers with a large number of I/Os). As another example, a large number of passive electronic components may be needed for different types of mobile devices (e.g., phones, tablets, etc.). The electronic packages and methods described herein may also be used for wearable electronic devices and other small form factor devices.

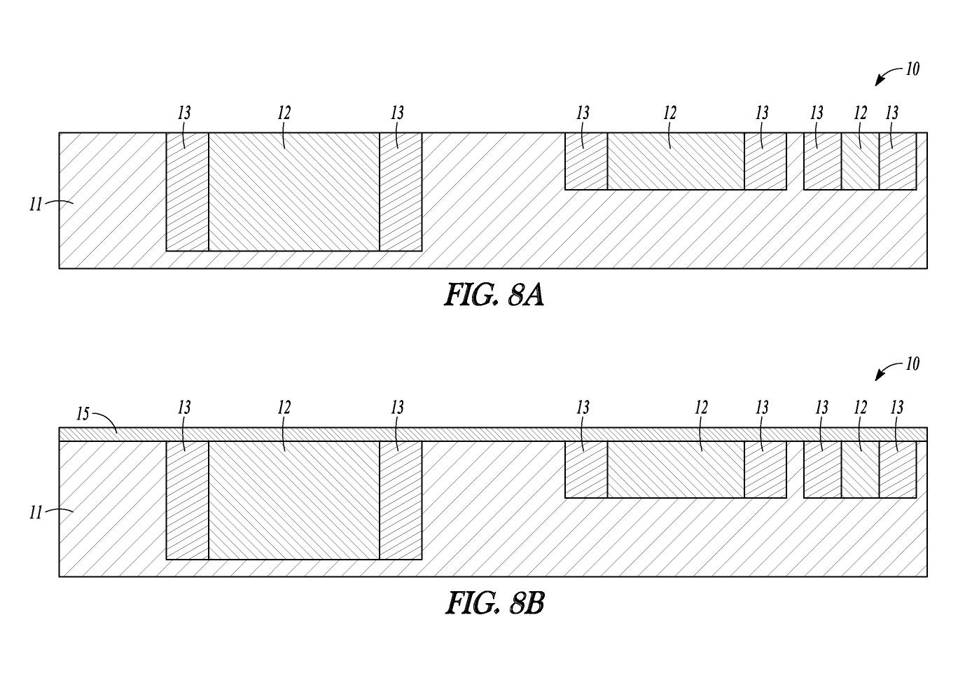

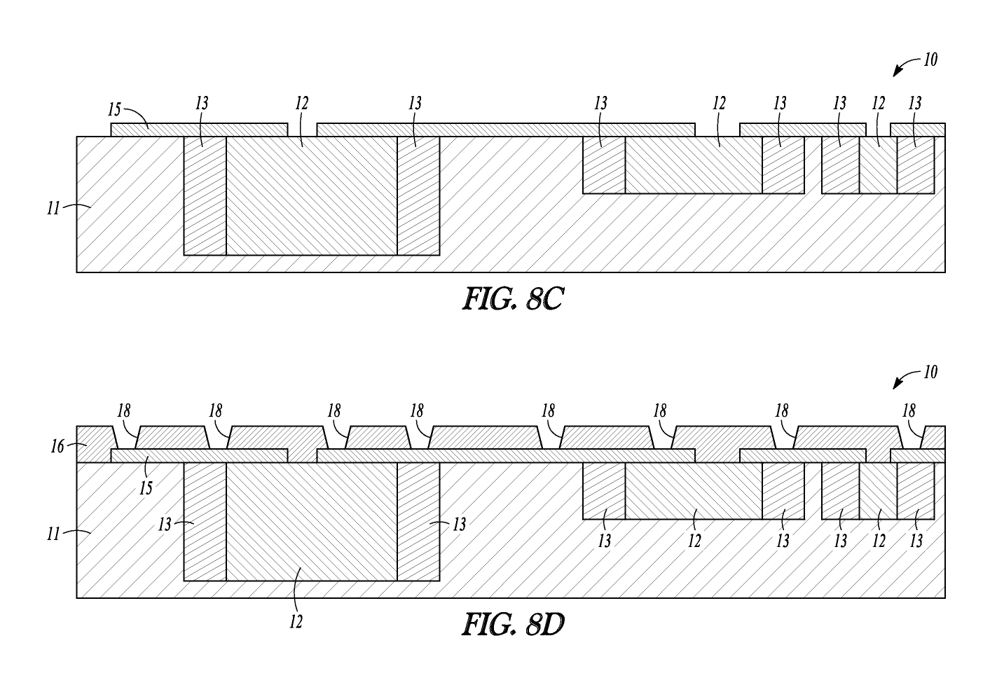

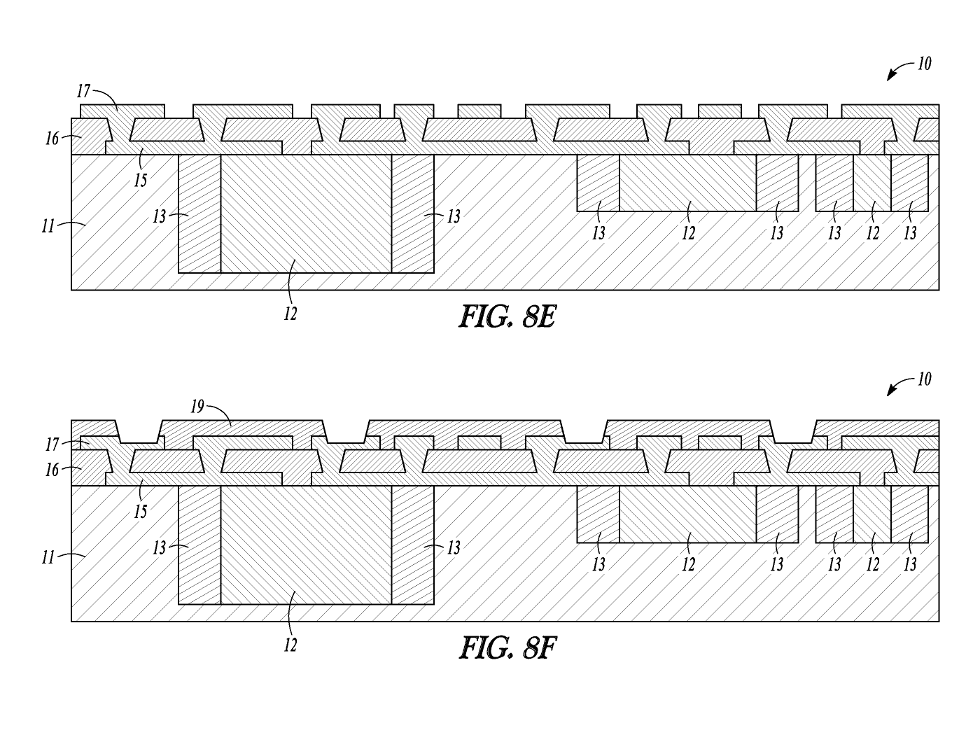

FIG. 6 illustrates one of the example electronic packages 10 described herein. The electronic package 10 includes a mold 11 that includes at least one passive component 12 (see also FIG. 8A). Each of the passive components 12 include electric conductors 13 that are exposed from the mold 11. The electronic package 10 further includes a first conductive layer 15 that is directly attached to the mold 11 such that the conductive layer 15 touches the mold 11 and the electrical conductors 13 that are exposed from the mold 11 (see also FIG. 8B).

In some forms of the electronic package 10, the mold 11 may further include at least one active component (not shown). Each of the active components may include electric conductors that are exposed from the mold 11 and touch the conductive layer 15. The type of passive and/or active components that are included in the mold 11 will depend in part on the overall desired configuration and function of the electronic package 10.

It should be noted that the conductive layer 15 may be a patterned first conductive layer 15. The patterned first conductive layer 15 may be configured such that the patterned first conductive layer 15 engages the electric conductors 13 that are exposed from the mold 11 (see also FIG. 8C).

The electronic package 10 may further include a patterned buildup layer 16 covering the patterned first conductive layer 15 (see also FIG. 8D). The patterned buildup layer 16 may be formed of a polyamide, epoxy, PBO (Polybenzoxozoles), BCB (Benzocyclobutene), or any other material that is known now or discovered in the future. The type of material that is used for the patterned buildup layer 16 will depend in part on cost, manufacturing considerations and the functionality associated with fabricating the electronic package 10 (among other factors).

The electronic package 10 may further include a patterned second conductive layer 17 that covers the patterned buildup layer 16 and fills openings 18 (FIG. 8D) in the patterned buildup layer 16 such that the patterned second conductive layer 17 is electrically connected to the patterned first conductive layer 15 (see also FIG. 8E). As an example, the first and/or second conductive layers 15, 17 may be made of gold, although any suitable electrical conductor may be used. The type of material that is used for the first and/or second conductive layers 15, 17 will depend in part on cost, manufacturing considerations and the functionality associated with fabricating the electronic package 10 (among other factors).

The electronic package 10 may further include a patterned solder resist 19 that covers the patterned second conductive layer 17 (see also FIG. 8F). As shown in FIG. 6, the plurality of electrical contacts 20 may extend through the patterned solder resist 19 such that the plurality of electrical contacts 20 are electrically connected to the patterned second conductive layer 17.

As an example, the electrical contacts 20 may be a conductive pad, although any suitable type of electrical contact may be used (e.g., solder bumps conductive paste, anisotropic conductive organic, etc.). The type of electrical contact 20 that is used in the electronic package 10 will depend in part on cost, manufacturing considerations and the functionality associated with fabricating the electronic package 10 (among other factors).

In addition, the electronic package 10 may further include a die (not shown in FIG. 6) that is attached to at least some of the plurality of electrical contacts 20. The type of die that is used in the electronic package 10, and the manner in which the die is attached to at least some of the plurality of electrical contacts 20, will depend in part on cost, manufacturing considerations and the functionality associated with fabricating the electronic package 10 (among other factors).

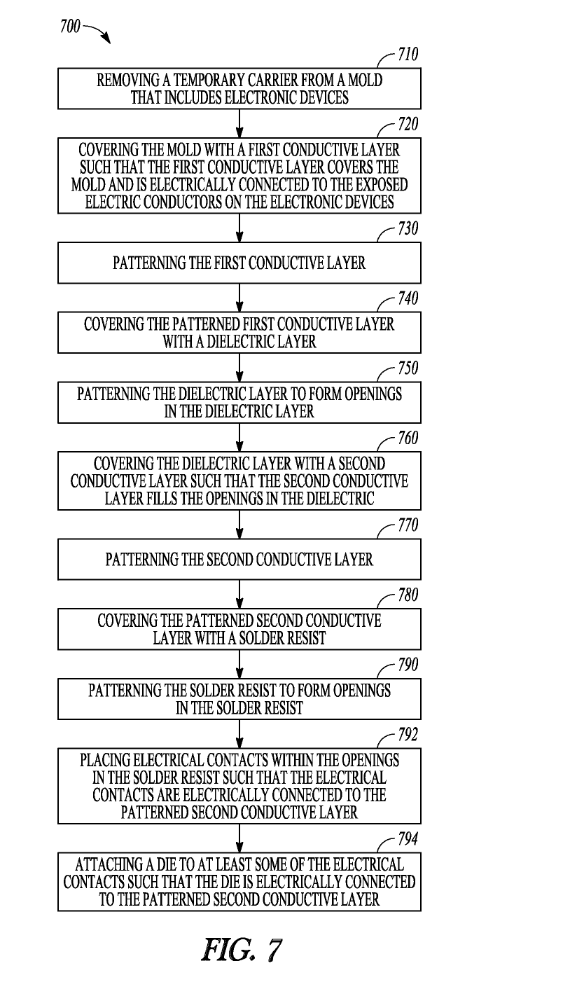

FIG. 7 illustrates a flow diagram of an example method [700] of forming an electronic package 10. FIGS. 8A-F show corresponding assemblies for portions of the method [700] shown in FIG. 7.

The method [700] includes [710] removing a temporary carrier with temporary adhesive (not shown) from a mold 11 that includes electronic devices 12 (e.g., passive and active electronic components). Electric conductors 13 on the electronic devices 12 are exposed once the temporary carrier with the temporary adhesive is removed from the mold 11 (see FIG. 8A).

The method [700] further includes [720] covering the mold 11 with a first conductive layer 15. The first conductive layer 15 covers the mold 11 and is electrically connected to the exposed electric conductors 13 on the electronic devices 12 (see FIG. 8B).

The first conductive layer 15 may be attached to the mold 11 using plating (or some other type of deposition) without using a mask directly onto the surface of eWLB wafers that include passive electronic devices 12 embedded in the eWLB wafers. The passive electronic devices 12 may (i) have different surface finishes; (ii) be formed of different material; and/or (iii) be different heights from the surface of the eWLB wafer. In some forms of the method [700], pulse plating the first conductive layer 15 onto the mold 11 may be used to overcome one or more of these differences. Example passive electronic devices 12 include resistor, capacitors, inductors and/or integrated passive devices.

Attaching the first conductive layer 15 directly to the mold 11 may reduce the effect of these differences thereby improving electrical interconnections within the electronic package 10. In addition, attaching the first conductive layer 15 directly to the mold 11 may serve to overcome tilting during poor pick-and-place assembly operation as well as the sometimes overly variable dimensions of some passive electronic devices 12.

The method [700] may further include [730] patterning the first conductive layer 15 (see FIG. 8C). It should be noted the first conductive layer 15 may be patterned any manner (e.g., etching) that is known or discovered in the future.

The method [700] may further include [740] covering the patterned first conductive layer 15 with a buildup layer 16, and [750] patterning the buildup layer 16 to form openings 18 in the buildup layer 16 (see FIG. 8D).

The method [700] may further include [760] covering the patterned buildup layer 16 with a second conductive layer 17. The second conductive layer 17 fills the openings in the patterned buildup layer 16 to electrically connect the second conductive layer 17 to the first conductive layer 15. The method [700] may also include [770] patterning the second conductive layer (see FIG. 8E).

The method [700] may further include [780] covering the patterned second conductive layer 17 with a solder resist 19, and [790] patterning the solder resist 19 to form openings in the solder resist 19 (see FIG. 8F).

The method [700] may further include [792] placing electrical contacts 20 within the openings in the solder resist 19. The electrical contacts 20 are electrically connected to the patterned second conductive layer 17 (as shown in FIG. 6).

The method [700] may further include [794] attaching a die to at least some of the electrical contacts 20. Therefore, the die is electrically connected to the patterned second conductive layer 17 (as shown in FIG. 6).

The interconnection between the die and the passive electronic devices 12 is accomplished with two conductive layers 15, 17 where the lower conductive layer 15 is deposited on an eWLB substrate directly (i.e., without having to use an extra buildup layer). The fan-out electrical connection to a BGA 22 is also done using the same conductive layers 15, 17.

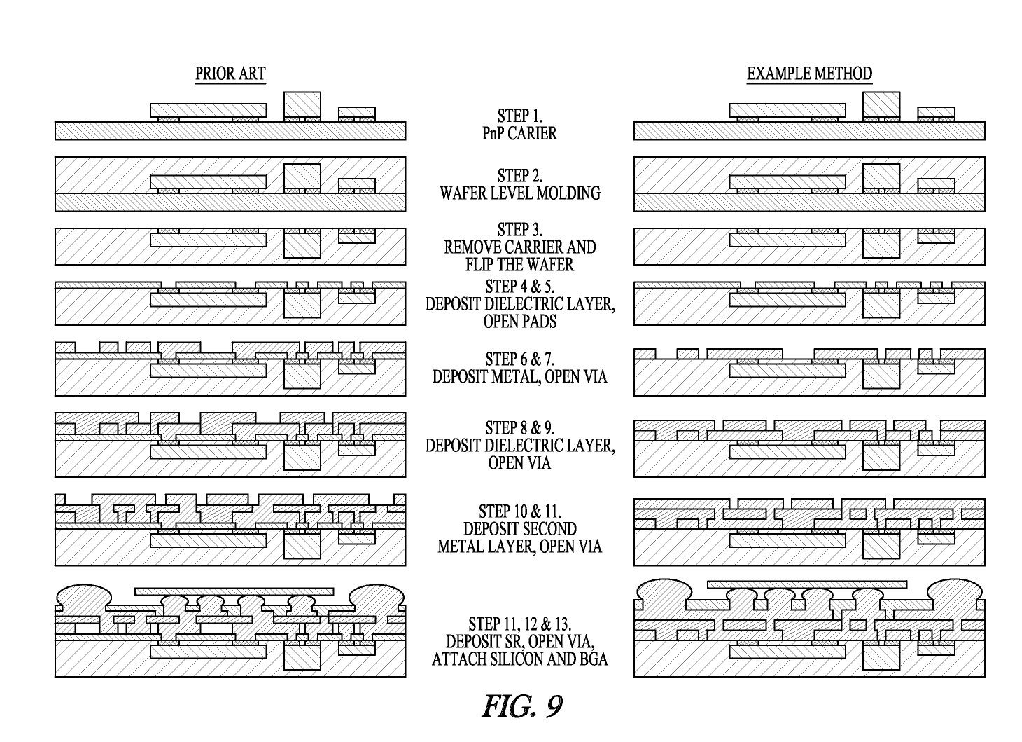

Therefore, the electronic package 10 and methods describe herein may reduce package cost by eliminating two fabrication steps used a conventional eWLB process (see FIG. 9): (i) buildup layer deposition over the mold layer; and (ii) drilling of vias through the buildup layer to make routing to other components.

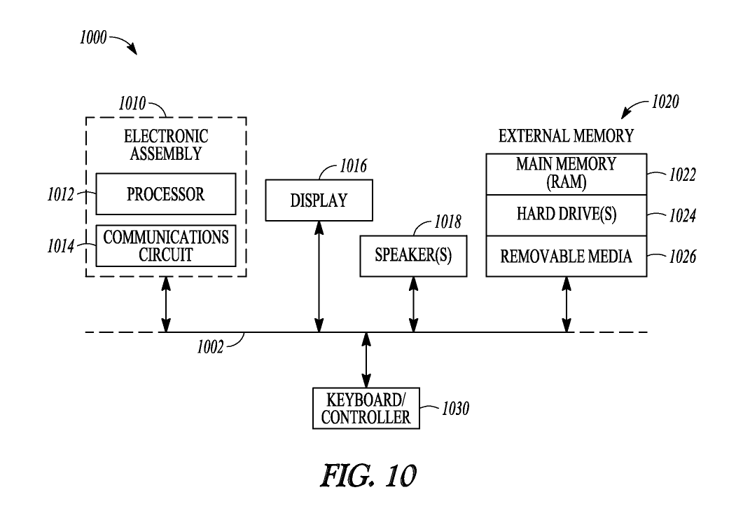

An example of an electronic package and methods as described in the present disclosure is included to show an example of a higher level application for the electronic package and methods. FIG. 10 is a block diagram of an electronic apparatus 1000 incorporating at least one electronic package and/or method described herein. Electronic apparatus 1000 is merely one example of an electronic system in which embodiments of the present invention can be used. Examples of electronic apparatuses 1000 include, but are not limited to personal computers, tablet computers, mobile telephones, game devices, MP3 or other digital music players, etc. In this example, electronic apparatus 1000 comprises a data processing system that includes a system bus 1002 to couple the various components of the system. System bus 1002 provides communications links among the various components of the electronic apparatus 1000 and can be implemented as a single bus, as a combination of busses, or in any other suitable manner.

An electronic package 1010 is coupled to system bus 1002. The electronic package 1010 can include any circuit or combination of circuits. In one embodiment, the electronic package 1010 includes a processor 1012 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic package 1010 are a custom circuit, an application-specific integrated circuit (ASIC), or the like, such as, for example, one or more circuits (such as a communications circuit 1014) for use in wireless devices like mobile telephones, tablet computers, laptop computers, two-way radios, and similar electronic systems. The IC can perform any other type of function.

The electronic apparatus 1000 can also include an external memory 1020, which in turn can include one or more memory elements suitable to the particular application, such as a main memory 1022 in the form of random access memory (RAM), one or more hard drives 1024, and/or one or more drives that handle removable media 1026 such as compact disks (CD), flash memory cards, digital video disk (DVD), and the like.

The electronic apparatus 1000 can also include a display device 1016, one or more speakers 1018, and a keyboard and/or controller 1030, which can include a mouse, trackball, touch screen, voice-recognition device, or any other device that permits a system user to input information into and receive information from the electronic apparatus 1000.

To better illustrate the method and apparatuses disclosed herein, a non-limiting list of embodiments is provided here:

Example 1 includes an electronic package that includes a mold that includes at least one passive component, each of the passive components including electric conductors that are exposed from the mold, and a first conductive layer directly attached to the mold such that the conductive layer touches the mold and the electrical conductors that are exposed from the mold.

Example 2 includes the electronic package of example 1, wherein the mold further includes at least one active component, each of the active components including electric conductors that are exposed from the mold and touch the conductive layer.

Example 3 includes the electronic package of any one of examples 1-2, wherein the at least one active component is a die.

Example 4 includes the electronic package of any one of examples 1-3, wherein the conductive layer is a patterned first conductive layer.

Example 5 includes the electronic package of any one of examples 1-4, and further including a patterned buildup layer covering the patterned first conductive layer.

Example 6 includes the electronic package of any one of examples 1-5, wherein the patterned buildup layer is formed of a polyamide epoxy.

Example 7 includes the electronic package of any one of examples 1-6, and further including a patterned second conductive layer that covers the patterned buildup layer and fills openings in the patterned buildup layer such that the patterned second conductive layer is electrically connected to the patterned first conductive layer.

Example 8 includes the electronic package of any one of examples 1-7, wherein the patterned first conductive layer and the patterned second conductive layer are copper.

Example 9 includes the electronic package of any one of examples 1-8, and further including a patterned solder resist covering the patterned second conductive layer.

Example 10 the electronic package of any one of examples 1-9, and further including a plurality of electrical contacts extending through the patterned solder resist such that the plurality of electrical contacts are electrically connected to the patterned second conductive layer.

Example 11 includes the electronic package of any one of examples 1-10, wherein the plurality of electrical contacts includes conductive pads.

Example 12 includes the electronic package of any one of examples 1-11, and further including a die attached to at least some of the plurality of electrical contacts.

Example 13 includes a method that includes removing a temporary carrier from a mold that includes electronic devices, wherein electric conductors on the electronic devices are exposed once the temporary carrier is removed from the mold, and covering the mold with a first conductive layer such that the first conductive layer covers the mold and is electrically connected to the exposed electric conductors on the electronic devices.

Example 14 includes the method of example 13, and further including patterning the first conductive layer.

Example 15 includes the method of any one of examples 13-14, and further including covering the patterned first conductive layer with a buildup layer; and patterning the buildup layer to form openings in the buildup layer.

Example 16 includes the method of any one of examples 13-15, and further including covering the buildup layer with a second conductive layer such that the second conductive layer fills the openings in the buildup layer to electrically connect the second conductive layer to the first conductive layer.

Example 17 includes the method of any one of examples 13-16, and further including patterning the second conductive layer, covering the patterned second conductive layer with a solder resist, and patterning the solder resist to form openings in the solder resist.

Example 18 includes the method of examples 13-17, and further including placing electrical contacts within the openings in the solder resist such that the electrical contacts are electrically connected to the patterned second conductive layer.

Example 19 includes the method of any one of examples 13-18, and further including attaching a die to at least some of the electrical contacts such that the die is electrically connected to the patterned second conductive layer.

Example 20 includes a method that includes removing a temporary carrier from a mold that includes an active electronic device and a passive electronic device, wherein electric conductors on the active electronic device and the passive electronic device are exposed once the temporary carrier is removed from the mold, covering the mold with a first conductive layer such that the first conductive layer covers the mold and is electrically connected to the exposed electric conductors on the active electronic device and the passive electronic device, patterning the first conductive layer, covering the patterned first conductive layer with a buildup layer, patterning the buildup layer to form openings in the buildup layer, covering the buildup layer with a second conductive layer such that the second conductive layer fills the openings in the buildup layer to electrically connect the second conductive layer to the first conductive layer, patterning the second conductive layer, covering the patterned second conductive layer with a solder resist, patterning the solder to form openings in the solder resist, placing electrical contacts within the openings in the solder resist such that the electrical contacts are electrically connected to the patterned second conductive layer, and attaching a die to at least some of the electrical contacts such that the die is electrically connected to the patterned second conductive layer.

This overview is intended to provide non-limiting examples of the present subject matter—it is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to comply with 37 C.F.R. §1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic package, comprising:
a mold that includes at least one passive component, each of the passive components including electric conductors that are exposed from the mold; and
a first conductive layer directly attached to the mold such that the conductive layer touches the mold and the electrical conductors that are exposed from the mold.

2. The electronic package of claim 1, wherein the mold further includes at least one active component, each of the active components including electric conductors that are exposed from the mold and touch the conductive layer.

3. The electronic package of claim 1, wherein the at least one active component die.

4. The electronic package of claim 1, wherein the conductive layer is a patterned first conductive layer.

5. The electronic package of claim 4, further comprising a patterned buildup layer covering the patterned first conductive layer.

6. The electronic package of claim 5, herein the patterned buildup layer is formed of a polyamide epoxy.

7. The electronic package of claim 5, further comprising a patterned second conductive layer that covers the patterned buildup layer and fills openings in the patterned buildup layer such that the patterned second conductive layer is electrically connected to the patterned first conductive layer.

8. The electronic package of claim 7, wherein the patterned first conductive layer and the patterned second conductive layer are copper.

9. The electronic package of claim 7, further comprising a patterned solder resist covering the patterned second conductive layer.

10. The electronic package of claim 9, further comprising a plurality of electrical contacts extending through the patterned solder resist such that the plurality of electrical contacts are electrically connected to the patterned second conductive layer.

11. The electronic package of claim 10, wherein the plurality of electrical contacts includes conductive pads.

12. The electronic package of claim 10, further comprising a die attached to at least some of the plurality of electrical contacts.

13. A method, comprising:
removing a temporary carrier from a mold that includes electronic devices, wherein electric conductors on the electronic devices are exposed once the temporary carrier is removed from the mold; and
covering the mold with a first conductive layer such that the first conductive layer covers the mold and is electrically connected to the exposed electric conductors on the electronic devices.

14-20. (canceled)
